(19) United States
(12) Patent Application Publication
(10) Pub. No.: US 2025/0298100 A1
(43) Pub. Date: Sep. 25, 2025

(54) SEPARABLE SPINE COIL

(71) Applicant: Siemens Healthineers AG, Forchheim (DE)

(72) Inventors: Stephan Biber, Erlangen (DE); Volker Matschl, Bamberg (DE); Antje Lohfink, Erlangen (DE); Sebastian Dennert, Lonnerstadt (DE)

(21) Appl. No.: 19/087,512

(22) Filed: Mar. 22, 2025

(30) Foreign Application Priority Data
Mar. 22, 2024 (DE) 10 2024 202 745.6

(51) Int. Cl. G01R 33/28; G01R 33/34

(52) U.S. Cl. CPC G01R 33/283; G01R 33/34046

(57) ABSTRACT

A spine coil, a system having a patient table and the spine coil, and a magnetic resonance apparatus are provided. The spine coil includes multiple parts that may be arranged separately from one another on the patient table of the magnetic resonance apparatus.

This application claims the benefit of German Patent Application No. DE 10 2024 202 745.6, filed on Mar. 22, 2024, which is hereby incorporated by reference in its entirety.

### BACKGROUND

The present embodiments relate to a spine coil, a system having a patient table and a spine coil, and a magnetic resonance apparatus.

Imaging procedures are important aids in medical technology. For example, imaging using magnetic resonance (MR) (e.g., magnetic resonance imaging (MRI)) is characterized by high and variable soft-tissue contrasts. Here, with the help of a magnetic resonance apparatus in a patient tunnel, for example, a spatially homogeneous main magnetic field is generated, in which a patient is located during a magnetic resonance scan. In this case, radio-frequency (RF) electromagnetic pulses are irradiated into the patient, so that atomic nuclei of the patient are excited. The excited atomic nuclei emit magnetic resonance signals that are received by local coils and are passed to an evaluation unit of the magnetic resonance apparatus. Based on the magnetic resonance signals received, the evaluation unit calculates magnetic resonance images.

Various types of local coils are known, each of which is intended for the examination of a specific area of the body, in the vicinity of which the local coils are arranged during the magnetic resonance scan. For example, head coils are employed for the examination of the patient's head. Spine coils are another type of local coil. A spine coil is normally located underneath the patient's back during the magnetic resonance scan. A number of variants are known here: a) the spine coil may be permanently integrated in the magnetic resonance apparatus (e.g., in the patient tunnel), where for the magnetic resonance scan, the patient lies on a patient table and is moved over the spine coil; b) the spine coil may be permanently integrated in a patient table, on which the patient lies during the magnetic resonance scan; and c) the spine coil may, if necessary, be arranged on the patient table, the patient being placed onto the spine coil for the magnetic resonance scan.

The patient may be arranged on the patient table in two different orientations: head-first (e.g., the patient's head is the first body part to be moved into the patient tunnel for the magnetic resonance scan); or feet-first (e.g., the patient's feet are the first body parts to be moved into the patient tunnel). The feet-first orientation may be preferred, since many patients find it unpleasant if their head is moved into the patient tunnel first.

When spine coils of type c) are used, the problem arises in examinations with a feet-first orientation that because of the typical length of this type of coil of approximately 120 cm and its intended positioning on the patient table only the lower subregion of the spine is covered by such a coil. Lengthening the spine coil by approximately 30-50 cm to cover a typical body length would make such a coil significantly more difficult to handle.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, handling of spine coils that are placed on a patient table for performance of a magnetic resonance scan is simplified. Independent of the grammatical term usage, individuals with male, female or other gender identities are included within the term.

A spine coil for examining a patient to be positioned on a patient table of a magnetic resonance apparatus is provided. In this case, the spine coil includes multiple (e.g., two or more) parts (e.g., separate parts). The multiple parts may be separated (e.g., nondestructively) from one another. For example, the multiple parts may be arranged separately from one another on the patient table of the magnetic resonance apparatus. For example, the number of multiple parts of the spine coil is precisely two or three.

These multiple parts themselves may not in this case (e.g., for the intended use and/or in the intended operation; when used as intended) be disassembled further (e.g., nondestructively) into further subparts and/or components. This, for example, does not rule out that the multiple parts are composed of multiple subparts and/or components (e.g., screws, etc.). However, for the normal operation of a magnetic resonance apparatus, there is no provision for the multiple parts to be disassembled into these subparts and/or components.

The possible separate arrangement of the multiple parts does not rule out that there are restrictions in the arrangement of the multiple parts. For example, it may be necessary to arrange the multiple parts on the patient table in a particular order.

The spine coil may therefore be multi-part or multi-piece. The multiple parts of the spine coil may be positioned separately on the patient table and/or may be removed from the patient table. By dividing the spine coil into multiple parts that may be placed separately onto the patient table, an overly cumbersome (e.g., single-part or single-piece) spine coil may be prevented, thereby making handling easier.

The spine coil may be configured to be arranged (e.g., positioned and/or placed) on a patient table of the magnetic resonance apparatus. The spine coil may be configured for the patient to be supported thereon during the examination.

The spine coil may be configured to receive magnetic resonance signals during the examination. The magnetic resonance signals to be received may be generated at least in part in a section of the patient's spine during the examination.

One possible form of embodiment of the spine coil provides that each of the multiple parts of the spine coil includes at least one receiving antenna for receiving magnetic resonance signals.

One possible form of embodiment of the spine coil provides that at least one of the multiple parts does not include a receiving antenna for receiving magnetic resonance signals and is configured to form, together with the other parts, a uniform (e.g., continuous) overall bearing surface for supporting the patient. The at least one part that does not include a receiving antenna for receiving magnetic resonance signals may be suitable for filling an otherwise resulting recess in a patient table.

The multiple parts may form a coherent spine coil if the multiple parts are arranged on the patient table of the magnetic resonance apparatus. For example, it is provided that the multiple parts may be assembled along the longitudinal axis of the patient or the center axis (e.g., z-axis or in parallel to the z-direction) of the patient tunnel of the magnetic resonance apparatus. The spine coil may be assembled from multiple parts along the longitudinal axis of the patient or the center axis (e.g., z-axis or in parallel to the z-direction) of the patient tunnel of the magnetic resonance apparatus.

The spine coil may have an overall bearing surface that is configured to support the patient's back thereon during the examination. The multiple parts of the spine coil may have partial bearing surfaces, respectively, that form the overall bearing surface if the multiple parts are arranged on the patient table of the magnetic resonance apparatus.

The overall bearing surface may have a length (e.g., in the z-direction) of at least 60 cm (e.g., at least 100 cm). The length may be the extension along the center axis (e.g., z-axis) of the patient tunnel if the spine coil is arranged on the patient table in accordance with the normal and/or intended use. The overall bearing surface may have a width (e.g., in the x-direction) of at least 30 cm (e.g., at least 40 cm). The spine coil may have a height (e.g., in the y-direction) of less than 10 cm (e.g., less than 6 cm).

In one embodiment, the x-direction is oriented perpendicular to the sagittal plane of the patient, the y-direction is oriented perpendicular to the frontal plane of the patient, and the z-direction is oriented perpendicular to the transversal plane of the patient if the patient is lying on the spine coil on his/her back.

The overall bearing surface of the spine coil may be flat and/or is molded to the anatomy of the patient's back. The overall bearing surface of the spine coil may have no significant elevations. The spine coil may not be intended to be placed onto the patient's stomach. The spine coil may be configured to absorb the load or weight of the patient.

One form of embodiment of the spine coil provides that the multiple parts have module interfaces that are configured to connect the multiple parts to one another (e.g., mechanically and/or for signal transmission).

The module interfaces may, for example, be or include plug-in connections. Such plug-in connections may, for example, include a plug and a corresponding jack. For example, a first one of the multiple parts of the spine coil includes a plug, and a second one of the multiple parts of the spine coil includes a corresponding jack.

A mechanical connection may be suitable for fastening the multiple parts to one another. A signal transmission connection may be suitable for transmitting magnetic resonance signals received from one part of the spine coil to another part of the spine coil. A signal transmission connection may, for example, be an electrical and/or optical connection. For example, an interface may have a combination of electrical and optical transmission modules.

One form of embodiment of the spine coil provides that at least one of the multiple parts has a coil-side system interface that is configured to convey signals from the spine coil to the magnetic resonance apparatus. The signals to be conveyed may, for example, be magnetic resonance signals received from the spine coil.

The magnetic resonance apparatus may, for example, include a head coil, where the signals to be conveyed may be transmitted to the head coil of the magnetic resonance apparatus. The signals to be conveyed may also be transmitted to the patient table of the magnetic resonance apparatus. From the head coil and/or the patient table, the signals may be transmitted further to other components of the magnetic resonance apparatus (e.g., an evaluation unit for the reconstruction of magnetic resonance images).

The system interface may, for example, include a plug-in connection part (e.g., a plug and/or or a jack). For example, the spine coil includes a plug, and the patient table includes a corresponding jack.

A connection for signal transmission via the coil-side system interface may be suitable for transmitting magnetic resonance signals received from the spine coil to the magnetic resonance apparatus. A signal transmission connection may, for example, be an electrical and/or optical connection. For example, the system interface may have a combination of electrical and optical transmission modules.

One form of embodiment of the spine coil provides that the spine coil includes an overall number N of receiving antennas for receiving magnetic resonance signals. A coil-side system interface includes a switching matrix. Each of the N receiving antennas is electrically connected to an input of the switching matrix in each case. The switching matrix is configured to switch the N inputs to M outputs of the switching matrix, where M<N.

Using the switching matrix, the receiving antennas from which magnetic resonance signals are to be transmitted to the magnetic resonance apparatus may be selected. This is, for example, of advantage if the magnetic resonance apparatus has fewer than N receiving channels.

One form of embodiment of the spine coil provides that the multiple parts of the spine coil include two parts, each with a length of between 30 and 100 cm. The length may be the extension of the part in the z-direction. Spine coil parts of this length may still be handled easily by an operator of the magnetic resonance apparatus (e.g., may be positioned on the patient table or be removed from the patient table).

One form of embodiment of the spine coil provides that the multiple parts are of equal size. In one embodiment, this provides that each part may be handled (e.g., positioned) on the patient table or removed from the patient table with the same minimal effort.

One form of embodiment of the spine coil provides that at least two of the multiple parts of the spine coil are identical as regards geometry and/or interfaces and/or antenna arrangement. This facilitates interchangeability of the multiple parts.

One form of embodiment of the spine coil provides that at least one of the multiple parts has seal(s) (e.g., sealing surfaces) for sealing joints with other parts and/or with the patient table. As a result, it is possible to prevent liquids from being able to penetrate into intermediate spaces between spine coil and patient table.

Further, a system that includes a patient table and a spine coil described above is provided. The patient table has a receptacle for receiving the spine coil. The features and advantages of the spine coil set out above may also be transferred to the system.

The receptacle may, for example, have a recess in the surface of the patient table. For example, the receptacle may correspond to the shape of the spine coil.

One form of embodiment of the system provides that the patient table in each case has a table-side system interface at both ends, where each of the two table-side system interfaces may be connected to a coil-side system interface of the spine coil. As a result, the spine coil may be positioned on the patient table in two different orientations along the z-direction, in that the spine coil is connected either to one or the other side of the patient table.

Further, a magnetic resonance apparatus having a spine coil as described above and/or a system as described above including a spine coil and a patient table is provided. The possible features and advantages set out above may also be transferred to the magnetic resonance apparatus.

### BRIEF DESCRIPTION OF THE DRAWINGS

Further advantages, features, and details of the present embodiments emerge from the example embodiments described below and based on the drawings. Parts corresponding to one another are provided with the same reference characters in all figures, in which:

FIG. 1 shows a magnetic resonance apparatus having a patient table and a spine coil lying thereon;

FIG. 2 shows a two-part spine coil;

FIG. 3 shows a magnetic resonance apparatus having a patient table and a three-part spine coil;

FIG. 4 shows a magnetic resonance apparatus having a patient table, a head coil, and a two-part spine coil;

FIG. 5 shows a patient table and a two-part spine coil, where one part does not have any receiving antennas; and

FIG. 6 shows a patient table and a spine coil having a switching matrix.

### DETAILED DESCRIPTION

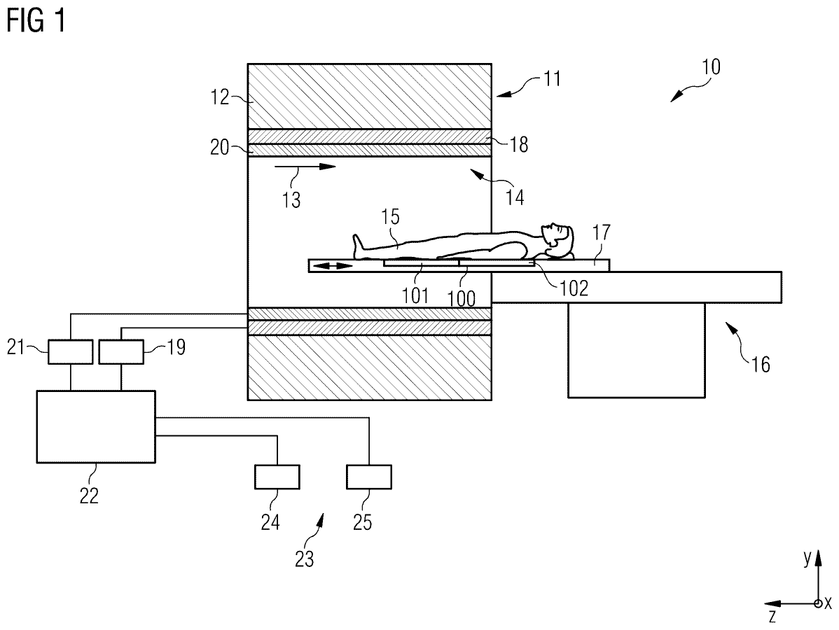

FIG. 1 shows a magnetic resonance apparatus 10 in a side view. The magnetic resonance apparatus 10 includes a magnet unit 11 that has a main magnet 12 to generate a main magnetic field 13 that is strong and, for example, constant over time. Further, the magnetic resonance apparatus 10 includes a patient tunnel 14 for receiving a patient 15. The patient tunnel 14 in the present example embodiment is configured to be cylindrical and is surrounded by the magnet unit 11 in a cylindrical shape in a circumferential direction. A center axis of the patient tunnel 14 is, for example, parallel to a z-axis of the magnetic resonance apparatus 10. The patient 15 may be moved into the patient tunnel 14 in the z-direction by a patient support apparatus 16 of the magnetic resonance apparatus 10. For this, the patient support apparatus 16 includes a patient table 17 movably configured inside the patient tunnel 14, on which the patient 15 is positioned. In this case, the patient 15 is, for example, in a feet-first orientation (e.g., the patient 15 is moved into the patient tunnel 14 feet-first).

The magnet unit 11 further has a gradient coil unit 18 for generating magnetic field gradients that are used for position encoding during imaging. The gradient coil unit 18 is controlled by a gradient control unit 19 of the magnetic resonance apparatus 10. The magnet unit 11 further includes a radio-frequency antenna unit 20 that, in the present example embodiment, is configured as a body coil permanently integrated in the magnetic resonance apparatus 10. The radio-frequency antenna unit 20 is controlled by a radio-frequency antenna control unit 21 of the magnetic resonance apparatus 10 and irradiates radio-frequency magnetic resonance sequences into an examination space that is substantially formed by a patient receiving area 14 of the magnetic resonance apparatus 10. As a result, the main magnetic field 13 generated by the main magnet 12 is caused to excite atomic nuclei. Magnetic resonance signals are generated by relaxation of the excited atomic nuclei. To receive the magnetic resonance signals, the magnetic resonance apparatus 10 includes a removable spine coil 100 on which the patient 15 is partially positioned. Removable or exchangeable local coils (e.g., spine coils) are, for example, of advantage if scans of different types of nuclei are to be performed, each of which is configured for a different receiving frequency. The spine coil 100 includes a first part 101 and a second part 102 that are arranged on the patient table 17 along the z-direction. By dividing the spine coil 100 into multiple parts along the z-direction, a large coverage may be achieved in the z-direction, where the individual parts may still be handled easily. Particularly with a feet-first orientation of the patient 15, this also helps to cover the area of the spine close to the head.

To control the main magnet 12 and the gradient control unit 19 and to control the radio-frequency antenna control unit 21, the magnetic resonance apparatus 10 has a system control unit 22. The system control unit 22 controls the magnetic resonance apparatus 10 centrally (e.g., the performance of a predetermined imaging gradient echo sequence). Further, the system control unit 22 includes an evaluation unit (not shown in greater detail) for the evaluation of the magnetic resonance signals captured during the magnetic resonance examination. Further, the magnetic resonance apparatus 10 includes a user interface 23 that is connected to the system control unit 22. Control information such as, for example, imaging parameters, as well as reconstructed magnetic resonance images, may be displayed on a display unit 24 (e.g., on at least one monitor) of the user interface 23 for a medical operative. The user interface 23 further has an input unit 25, by which information and/or parameters may be input by the medical operative during a scanning procedure.

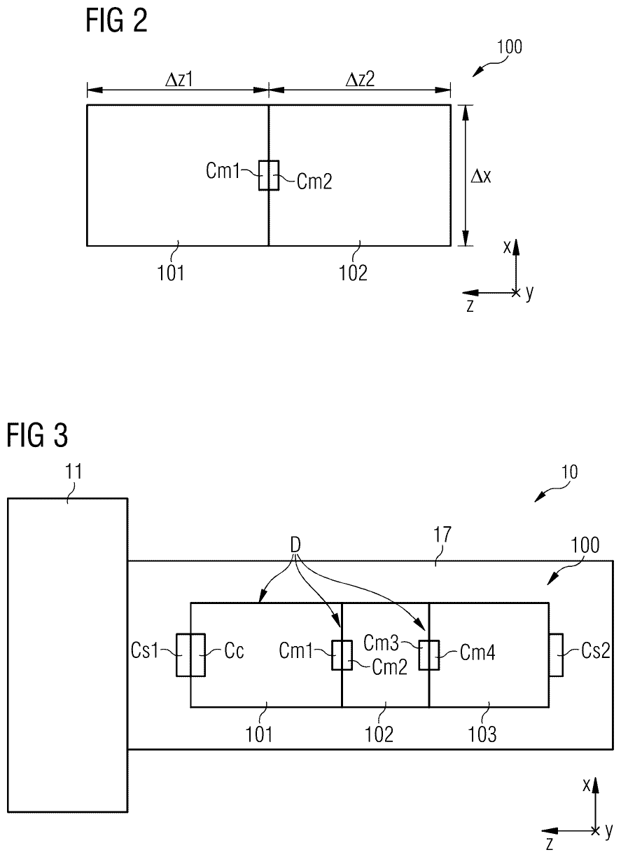

FIGS. 2 to 6 show different plan views of possible example embodiments. FIG. 2 shows a spine coil 100 having two parts 101, 102. In the z-direction, a first part 101 has a length Δz1, and a second part 102 has a length Δz2. The length Δz1 or Δz2 may be in each case between 30 cm and 100 cm. The lengths may be of equal size (e.g., Δz1=Δz2). The width Δx in the x-direction may be at least 30 cm (e.g., at least 40 cm). The first part therefore has a partial bearing surface with the dimensions Δz1×Δx. The second part therefore has a partial bearing surface with the dimensions Δz2×Δx. The overall bearing surface is thus (Δz1+Δz2)×Δx.

The first part includes a plug-in connection part Cm1 (e.g., a plug), and the second part includes a plug-in connection part Cm2 (e.g., a jack). Together, the plug-in connection parts Cm1, Cm2 form a module interface that is configured to connect both the parts 101, 102 to one another. For example, the plug-in connection parts Cm1, Cm2 may connect both the parts 101, 102 mechanically and/or electrically to one another. For example, magnetic resonance signals that are received by the spine coil 100 or its antennas may be transmitted via the electrical connections. A mechanical connection may provide that both the parts 101, 102 are fastened to one another, so that the spine coil 100 provides a stable support for the patient 15 if the patient 15 is positioned on the spine coil 100.

Thanks to the separable structure of a spine coil 100, an overall large extension in the z-direction is enabled, so that all examinations on a patient 15 may be performed not only in the head-first position but also in the feet-first position.

FIG. 3 shows a magnetic resonance apparatus 10 having a patient table 17 that is, for example, located outside the magnet unit 11. Arranged on the patient table 17 is a spine coil 100 that, for example, has three parts 101, 102, 103. Each of the three parts 101, 102, 103 may be arranged on the patient table 17 separately from the other parts.

The first part 101 includes a plug-in connection part Cm1 that is connected to the plug-in connection part Cm2 of the second part 102. The second part 102 further includes a plug-in connection part Cm3 that is connected to the plug-in connection part Cm4 of the third part 103. The plug-in connection parts Cm1 and Cm2 or Cm3 and Cm4 each form a module interface. Signals may be transmitted to the first part 101 via these module interfaces. For example, magnetic resonance signals received with the third part 103 may be transmitted to the second part via the plug-in connection parts Cm3, Cm4 and then further to the first part 101 via the plug-in connection parts Cm1, Cm2.

The first part includes a coil-side system interface Cc (e.g., in the form of a plug-in connection part) that is configured to transmit signals from the spine coil 100 to the patient table 17. For this, the patient table 17 includes at an end close to the patient tunnel a table-side system interface Cs1 corresponding to the coil-side system interface that, for example, is connected to the coil-side system interface Cc. At the end of the patient table 17 remote from the patient tunnel, the patient table 17 has a further table-side system interface Cs2. This makes it possible also to arrange the spine coil 100 on the patient table 17 rotated by 180° about the y-axis, so that then the coil-side system interface Cc would be connected to the table-side system interface Cs2.

At the joints D of the parts 101, 102, 103 to one another and to the patient table 17, the parts 101, 102, 103 may be provided with sealing surfaces, so that liquids cannot penetrate into the intermediate spaces between the spine coil 100 and the patient table 17.

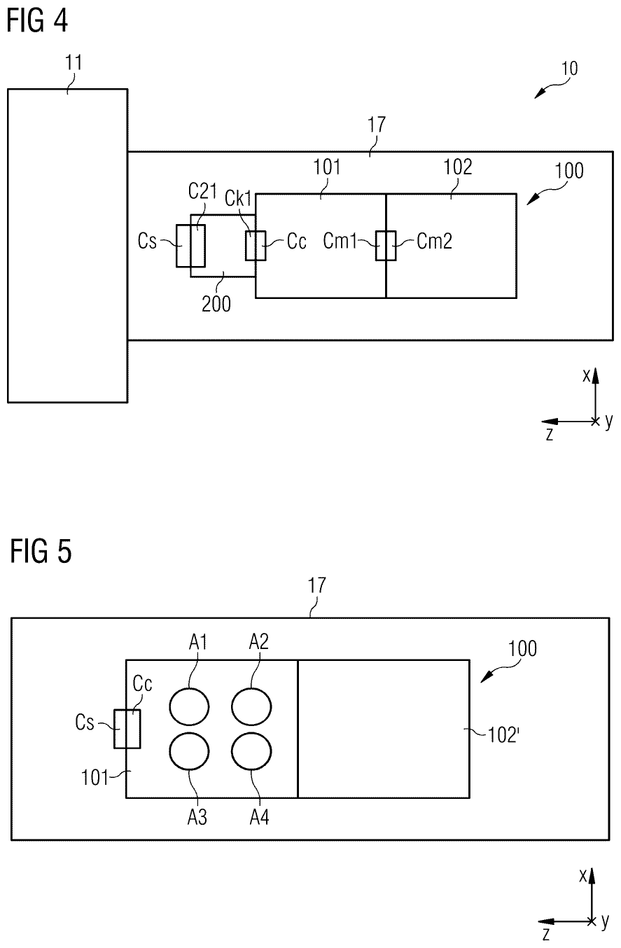

FIG. 4 shows a magnetic resonance apparatus 10 with a patient table 17, on which a head coil 200 and a two-part spine coil 100 are arranged. The head coil 200 may be employed in magnetic resonance examinations of the head of the patient 15 or is intended to acquire magnetic resonance signals of the head of the patient 15. The head coil 200 may have an interior imaging volume, in which the head or a part of the head may be arranged. The imaging volume may, for example, be delimited by an upper part and a lower part of the head coil 200.

Magnetic resonance signals may be received with the first part 101 and/or the second part 102 of the spine coil 100. Magnetic resonance signals received with the first part 101 may be transmitted directly to the head coil 200 via the spine-coil-side system interface Cc and the first head-coil-side interface Ck1. Magnetic resonance signals received with the first part 101 may initially be transmitted to the first part 101 via the plug-in connection parts Cm1 and Cm2. From the head coil 200, the magnetic resonance signals may be transmitted to the table-side system interface Cs of the patient table 17 via the second head-coil-side interface Ck2.

In one embodiment, the parts 101, 102 may be identical in structure (e.g., as regards geometry, plugs, antenna structure). In one embodiment, the parts may be exchanged. For example, if one of the parts fails, only this part needs to be replaced.

In one embodiment, only the first part alone may be used, thus without the second part (e.g., for applications in which also an overall shorter spine coil is sufficient and/or for patient tables that in any case have a smaller possible travel path).

FIG. 5 shows a spine coil 100 having only one active part. The spine coil 100 includes a first part 101 with four receiving antennas A1, A2, A3, A4 for receiving magnetic resonance signals (e.g., this is the active part). The spine coil 100 further includes a second part 102′ that does not have any receiving antennas. The second part 102′, for example, represents a (merely) mechanical addition to the first part 101 to fill the recess in the patient table 17 to receive the spine coil 100. As a result, a continuously flat bearing surface to support the patient 15 may be provided.

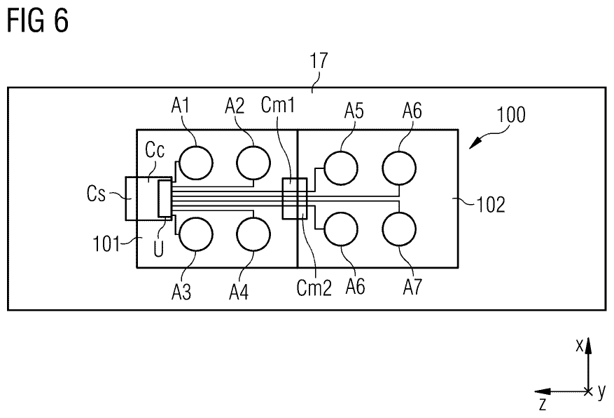

FIG. 6 shows a spine coil 100 having a switching matrix U on a patient table 17. The switching matrix U is, for example, part of the coil-side system interface Cc. The receiving antennas A1, A2, A3, A4 of the first part 101 of the spine coil 100 are directly connected to the switching matrix U, and the receiving antennas A5, A6, A7, A8 are connected via the plug-in connection parts Cm1 and Cm2. Each of these eight receiving antennas A1, A2, A3, A4, A5, A6, A7, A8 corresponds to a receiving channel in each case. The switching matrix U thus has, for example, eight inputs and four outputs. The switching matrix U is in this example able to switch from these eight receiving channels to a subset of four receiving channels; thus, only a subset of the receiving channels or of the signals of the corresponding receiving elements are forwarded to the patient table 17 via the system interface Cs.

The spine coil and the magnetic resonance apparatus described in detail above relate solely to example embodiments that may be modified by the person skilled in the art in a variety of ways without departing from the scope of the invention. Further, the use of the indefinite article “a” or “an” does not rule out that the features in question may also be present multiple times. Likewise, the term “unit” does not rule out that the components in question consist of multiple interacting subcomponents that, if appropriate, may also be distributed spatially.

The elements and features recited in the appended claims may be combined in different ways to produce new claims that likewise fall within the scope of the present embodiments. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A spine coil for examination of a patient to be positioned on a patient table of a magnetic resonance apparatus, the spine coil comprising:
multiple parts that are arrangeable separately from one another on the patient table of the magnetic resonance apparatus.

2. The spine coil of claim 1, wherein the multiple parts have at least one module interface that is configured to connect the multiple parts to one another.

3. The spine coil of claim 1, wherein at least one of the multiple parts has a coil-side system interface that is configured to convey signals from the spine coil to the magnetic resonance apparatus.

4. The spine coil of claim 3, wherein the coil-side system interface is configured to convey the signals from the spine coil to the patient table, a head coil, or the patient table and the had coil.

5. The spine coil of claim 3, further comprising an overall number N of receiving antennas for receiving magnetic resonance signals,
wherein the coil-side system interface comprises a switching matrix,
wherein each of the N receiving antennas is electrically connected to an input of the switching matrix in each case, and
wherein the switching matrix is configured to switch the N inputs to M outputs of the switching matrix, M being less than N.

6. The spine coil of claim 1, wherein the multiple parts of the spine coil comprise two parts, each with a length of between 30 and 100 cm.

7. The spine coil of claim 1, wherein at least two of the multiple parts of the spine coil are identical as regards geometry, interfaces, antenna arrangement, or any combination thereof.

8. The spine coil of claim 1, wherein at least one of the multiple parts has a seal for sealing joints to other parts, to the patient table, or to the other parts and the patient table.

9. The spine coil of claim 1, wherein each of the multiple parts comprises at least one receiving antenna for receiving magnetic resonance signals.

10. The spine coil of claim 1, wherein at least one of the multiple parts does not comprise a receiving antenna for receiving magnetic resonance signals and is configured to form, together with other parts, a uniform overall bearing surface for supporting the patient.

11. A system comprising:
a patient table; and
a spine coil for examination of a patient to be positioned on the patient table, the spine coil comprising:
multiple parts that are arrangeable separately from one another on the patient table,
wherein the patient table has a receptacle for receiving the spine coil.

12. The system of claim 11, wherein at both ends of the patient table, the patient table has a table-side system interface in each case, and
wherein each of the two table-side system interfaces is configured to be connected to a coil-side system interface of the spine coil.

13. A magnetic resonance apparatus comprising:
a spine coil for examination of a patient to be positioned on a patient table, the spine coil comprising:
multiple parts that are arrangeable separately from one another on the patient table.

14. The magnetic resonance apparatus of claim 13, further comprising:
a patient table has a receptacle for receiving the spine coil.

15. The magnetic resonance apparatus of claim 14, wherein at both ends of the patient table, the patient table has a table-side system interface in each case, and
wherein each of the two table-side system interfaces is configured to be connected to a coil-side system interface of the spine coil.
